(19) United States
(12) Patent Application Publication
(10) Pub. No.: US 2026/0164723 A1
(43) Pub. Date: Jun. 11, 2026

(54) Switching element with reduced effects from a sub-channel

(71) Applicant: InnoLux Corporation, Miao-Li County (TW)

(72) Inventors: Sheng-Feng HUANG, Miao-Li County (TW); Yu-Mei CHIU, Miao-Li County (TW); Yung-Shun YANG, Miao-Li County (TW); Fu-Min WANG, Miao-Li County (TW)

(73) Assignee: InnoLux Corporation, Miao-Li County (TW)

(21) Appl. No.: 19/387,699

(22) Filed: Nov. 13, 2025

(30) Foreign Application Priority Data
Dec. 11, 2024 (CN) 202411815593.7

(51) Int. Cl. H10D 30/67

(52) U.S. Cl. CPC H10D 30/6757; H10D 30/6715; H10D 30/6745

(57) ABSTRACT

A switching element has a gate and a semiconductor. The semiconductor includes a first region, a second region, and a third region. The first region is located between the second region and the third region. The first region includes at least one first subregion and a second subregion other than the at least one first subregion, and the at least one first subregion is adjacent to a side of the semiconductor. In a top view of the switching element, at least a portion of the first region overlaps with the gate. An ion concentration doped in the at least one first subregion is different from an ion concentration doped the second subregion.

### BACKGROUND OF THE DISCLOSURE

### 1. Field of the Disclosure

The present disclosure relates to a switching element, specifically to a switching element that reduces the presence and/or effects of a sub-channel.

### 2. Description of the Prior Art

Switching elements, such as top-gate low-temperature polysilicon thin-film transistors (LTPS TFTs), due to their unique process structure, often exhibit sub-channel phenomena in their current-voltage (I-V) curves. This sub-channel effect can lead to significant variations in the electrical performance of switching elements, especially under stress conditions, where the differences between the sub-channel and main channel characteristics become more pronounced, and may even result in the degradation and/or failure of the switching element.

### SUMMARY OF THE DISCLOSURE

According to some embodiments, the present disclosure provides a switching element comprising a gate and a semiconductor. The semiconductor comprises a first region, a second region, and a third region. The first region is located between the second region and the third region. The first region comprises at least one first subregion and a second subregion other than the at least one first subregion, and the at least one first subregion being adjacent to a side of the semiconductor. In a top view of the switching element, at least a portion of the first region overlaps with the gate. An ion concentration doped in the at least one first subregion is different from an ion concentration doped in the second subregion.

According to some embodiments, the present disclosure provides a switching element comprising a gate and a semiconductor. The semiconductor comprises a first region, a second region, and a third region. The first region is located between the second region and the third region. The first region comprises two first subregions and a second subregion other than the two first subregions. Each first subregion is adjacent to a corresponding side of the semiconductor. In a top view of the switching element, at least a portion of the each first subregion overlaps with the gate. An ion concentration doped in the each first subregion is different from an ion concentration doped in the second subregion.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a top view of a switching element according to an embodiment of the present disclosure.

FIG. 2 is a cross-sectional view of the switching element in FIG. 1 along the dash line 2-2′.

FIG. 3 is a current-voltage (IV) curve diagram of the switching element in FIG. 1.

FIG. 4 is a top view of a switching element according to another embodiment of the present disclosure.

FIG. 5 is a top view of a switching element according to another embodiment of the present disclosure.

FIG. 6 is a top view of a switching element according to another embodiment of the present disclosure.

### DETAILED DESCRIPTION

This disclosure can be understood by reference to the following detailed description taken in conjunction with the accompanying drawings. For ease of understanding and simplicity of the drawings, only a portion of the electronic device is illustrated in the various figures, and the specific components in the figures are not drawn to scale. Furthermore, the number and size of the components in the figures are for illustrative purposes only and are not intended to limit the scope of this disclosure.

In the specification and claims, certain terms are used to refer to particular components. It should be understood by those skilled in the art that electronic device manufacturers may refer to the same component by different names. It is not intended herein to distinguish between those components that, although different in name, are identical in function.

As used throughout this specification and the appended claims, the terms “comprising,” “including,” and “having” are to be construed as being open-ended terms and thus should be interpreted as meaning “including, but not limited to.” Accordingly, when the specification uses the terms “comprising,” “including,” and/or “having,” it is contemplated that features, elements, steps, operations, elements, and/or components are included, but that other features, elements, steps, operations, elements, and/or components are not excluded.

Directional terms used herein, such as “upper,” “lower,” “front,” “back,” “left,” and “right,” are merely for convenience in describing the figures. Thus, the directional terms are intended to be illustrative and not limiting. The figures illustrate the general nature of the methods, structures, and/or materials used in particular embodiments. However, the figures should not be construed as defining or limiting the scope or nature of the invention as encompassed by these embodiments. For example, for clarity, the relative sizes, thicknesses, and positions of various layers, regions, and/or structures may be exaggerated or minimized.

When a component (such as a layer or region) is said to be “on” another component, it can be directly on the other component, or there can be intervening components. On the other hand, when a component is said to be “directly on” another component, there are no intervening components. Additionally, when one component is said to be “on” another component, the two are vertically related, and the component can be above or below the other component, depending on the orientation of the device.

It should be understood that when a component or layer is said to be “connected to” another component or layer, it can be directly connected to the other component or layer, or there can be intervening components or layers. When a component is said to be “directly connected to” another component or layer, there are no intervening components or layers. Additionally, when a component is said to be “coupled to another component (or variations thereof),” it can be directly electrically connected to the other component, or it can be indirectly connected (e.g., indirectly electrically connected) to the other component through one or more intervening components.

In this disclosure, when one component is “disconnected” from another component, an electrical signal cannot flow between the two components at the specified time.

The terms “approximately” or “about” are generally to be construed as being within ±10% of a given value, or construed as being within ±5%, ±3%, ±2%, ±1%, or ±0.5% of a given value.

The use of ordinal terms such as “first,” “second,” and the like to modify the elements in the specification and claims is intended solely to distinguish one element having that identifier from another element having the same identifier. It is not intended to imply any sequence or order among such elements, or any temporal order in which such elements may be manufactured. The use of such ordinal terms is merely to facilitate distinguishing between elements having the same identifier. The specification and the claims may use different ordinal terms. Accordingly, a first element in the specification may be a second element in the claim.

It should be understood that the features of the different embodiments described below can be interchanged, recombined, or combined with each other to form other embodiments without departing from the spirit and scope of the disclosure.

In this disclosure, the electronic device can include, but is not limited to, a display device, a light emitting device, an antenna device, a sensing device, a medical device, a splicing device, or any combination thereof. The display device can be a non-emissive display or an emissive display, depending on the need, and can be a color display or a monochrome display, depending on the need. The antenna device can be a liquid crystal type antenna device or a non-liquid crystal type antenna device. The sensing device can be a sensor for sensing capacitance, light, heat, or ultrasound. The medical device can be a medical examination device. The splicing device can be a display splicing device or an antenna splicing device, but is not limited thereto. The electronic device can include electronic components, and the electronic components can include passive components and active components, such as capacitors, resistors, inductors, diodes, electrowetting elements, switching elements, dies, or chips. The diode can be a die or a chip, and can include a light emitting diode (LED) or a photodiode or a varactor diode, but is not limited thereto. The light emitting diode can include, for example, an organic light emitting diode (OLED) or an inorganic light emitting diode. The inorganic light emitting diode can include a mini LED, a micro LED, or a quantum dot LED, but is not limited thereto. The electrowetting element can include, for example, a digital microfluidic (DMF) platform, an electrowetting display, or an electro-wetting-on-dielectric on lab-on-chip application, but is not limited thereto. The switching element can be a transistor, and the transistor can include, for example, a top gate thin-film transistor, a bottom gate thin-film transistor, or a dual gate thin-film transistor, but is not limited thereto. The electronic device can also include, depending on the need, fluorescent materials, phosphorescent materials, quantum dot (QD) materials, or other suitable materials, but is not limited thereto. The electronic device may have a driving system, a control system, a light source system, and other peripheral systems to support the devices and components in the electronic device.

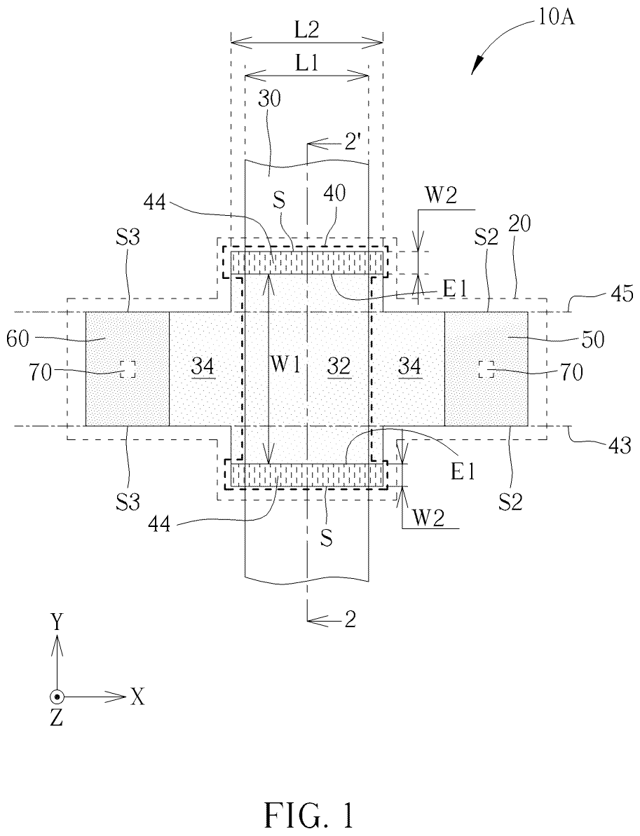

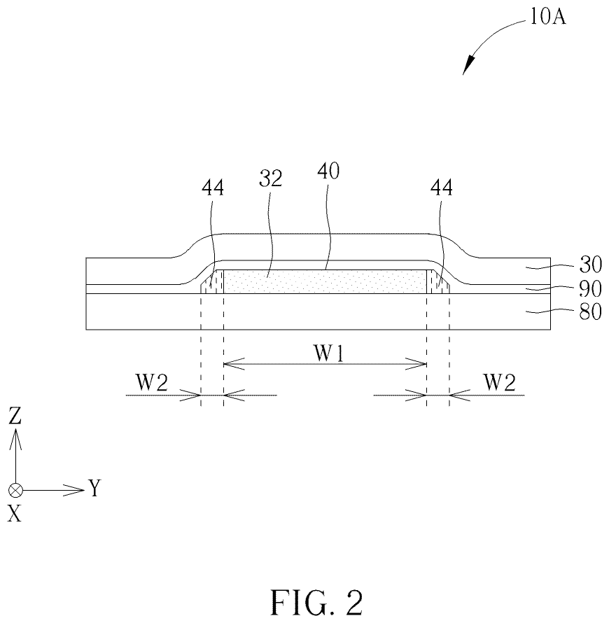

Please refer to FIG. 1 and FIG. 2. FIG. 1 is a top view of a switching element 10A according to an embodiment of the present disclosure. The switching element 10A may be used in any electronic device and is disposed on a substrate of the electronic device. The switching element 10A may be electrically connected to other electronic components disposed on the substrate of the electronic device and may control these electronic components. FIG. 2 is a cross-sectional view of the switching element 10A in FIG. 1 along a dash line 2-2′. In the embodiment, the top view in FIG. 1 extends along the directions X and Y, and the cross-sectional view in FIG. 2 extends along the directions Y and Z. The directions X, Y, and Z are different from each other and may be mutually perpendicular in one embodiment. In the embodiment, the switching element 10A may be an N-type transistor, which includes a gate 30 and a semiconductor 20. In other embodiments of the present disclosure, the switching element 10A may be a P-type transistor. The semiconductor 20 may be formed and disposed on a substrate 80. The material of the substrate 80 can include organic materials or inorganic materials. Examples of organic materials include polyimide (PI), and examples of inorganic materials include silicon, germanium, glass, quartz, sapphire, and the like, but are not limited thereto. The semiconductor 20 can form a source region, a channel region, and a drain region of the switching element 10A, and its material may be polycrystalline silicon, oxide semiconductor, amorphous silicon, silicon germanium (SiGe), gallium arsenide (GaAs), or silicon carbide (SiC), but is not limited thereto. The semiconductor 20 comprises a first region 40, a second region 50, and a third region 60, wherein the first region 40 is located between the second region 50 and the third region 60. In one embodiment, the first region 40 comprises two first subregions 44 and a second subregion 32 other than the two first subregions 44. In other words, each of the two opposite edges E1 of the second subregion 32 is directly connected to one of the first subregions 44. In other embodiments of the present disclosure, the number of first subregions 44 included in the switching element may be one. For example, the switching element 10A may comprise a single first subregion 44 located above or below the second subregion 32. The semiconductor 20 is covered by a gate insulator 90 (as shown in FIG. 2) and is interposed between the semiconductor 20 and the gate 30. The material of the gate insulator 90 may be silicon dioxide (SiO₂), aluminum oxide (Al₂O₃), hafnium dioxide (HfO₂), or silicon nitride (Si₃N₄), but is not limited thereto. The gate 30 is formed on the gate insulator 90, and its material may be metal, metal alloy, polycrystalline silicon, tantalum nitride (TaN), titanium nitride (TiN), hafnium metal (Hf), or silicon germanium (SiGe), but is not limited thereto. The gate 30 may have a single-layer structure or a multi-layer structure.

In the embodiment, the semiconductor 20 has a plurality of sides S, each of the first subregions 44 is adjacent to one of the sides S of the semiconductor 20, and the two first subregions 44 are respectively adjacent to two opposite sides S of the semiconductor 20. Furthermore, in the top view of the switching element 10A, at least a portion of the first region 40 overlaps with the gate 30. The second subregion 32 is the channel region of the switching element 10A. In the top view of the switching element 10A, the second subregion 32 overlaps with the gate 30. The first subregions 44 and the second subregion 32 may be formed by doping with the same ions, but the ion concentration doped in each first subregion 44 is different from the ion concentration doped in the second subregion 32. The ions doped in the first subregions 44 and the second subregion 32 may be boron ions, but are not limited thereto. In some embodiments of the present disclosure, the first subregions 44 may be P-type heavily doped regions (P+), and the second subregion 32 may be a P-type lightly doped region (P−). The ion concentration doped in each first subregion 44 may be 2 to 1000 times the ion concentration doped in the second subregion 32. In other words, the ratio of the ion concentration doped in each first subregion 44 to the ion concentration doped in the second subregion 32 is greater than or equal to 2 and less than or equal to 1000.

Please continue to refer to FIG. 1. The second region 50 and the third region 60 are arranged along the direction X, and each first subregion 44 is located outside an area formed between two connection lines 43 and 45 of the sides S2 of the second region 50 and the sides S3 of the third region 60. In other words, the second region 50 and the third region 60 are located within the area formed by the connection lines 43 and 45. The connection lines 43 and 45 may be parallel to the direction X. In other embodiments of the present disclosure, each first subregion 44 may be partially located outside the area formed between the two connection lines 43 and 45, and partially located within the area formed between the two connection lines 43 and 45. In the embodiment, the sides S of the semiconductor 20 can also serve as the sides of the first subregions 44. The distance L2 in the direction X between the two sides of each first subregion 44 is greater than or equal to the distance L1 in the direction X between the two sides of the gate 30. The two sides of the first subregion 44 and the two sides of the gate 30 mentioned here may be, for example, parallel to the direction Y. In other embodiments of the present disclosure, the two sides of the first subregion 44 and the two sides of the gate 30 are not all parallel to the direction Y, and the distance L2 between the two sides of the first subregion 44 and the distance L1 between the two sides of the gate 30 may be measured in a cross-section parallel to the direction X.

In addition, the gate 30 extends in the direction Y. In the embodiment, along the direction Y, the distance W2 between a side (adjacent to the side S of the semiconductor 20) and an edge (adjacent to the edge E1 of the second subregion 32) of each first subregion 44 is less than the distance W1 between the two edges E1 of the second subregion 32. The sides S and the edges E1 may be parallel to the direction X. In other embodiments of the present disclosure, the distance W2 in the direction Y between the side S and the edge E1 of each first subregion 44 may be greater than or equal to the distance W1 in the direction Y between the two edges E1 of the second subregion 32.

The second region 50 and the third region 60 may be N-type heavily doped regions (N+), respectively becoming the drain region and the source region of the switching element 10A. Additionally, the semiconductor 20 may further comprise two lightly doped regions (LDDs) 34, and each lightly doped region 34 may be an N-type lightly doped region (N−). The ions doped in the second region 50, the third region 60, and the two lightly doped regions 34 may be phosphorus ions or arsenic ions, but are not limited thereto. Furthermore, in the top view of the switching element 10A, the second region 50, the third region 60, and the two lightly doped regions 34 do not overlap with the gate 30. Additionally, since the gate insulator layer 90 covers the semiconductor 20, the gate insulator layer 90 may comprise vias 70, which overlap with the second region 50 and the third region 60, respectively. Other conductive layers or metal layers disposed on the gate insulator layer 90 may be coupled to the second region 50 and/or the third region 60 through the vias 70 to transmit voltages or currents of the switching element 10A.

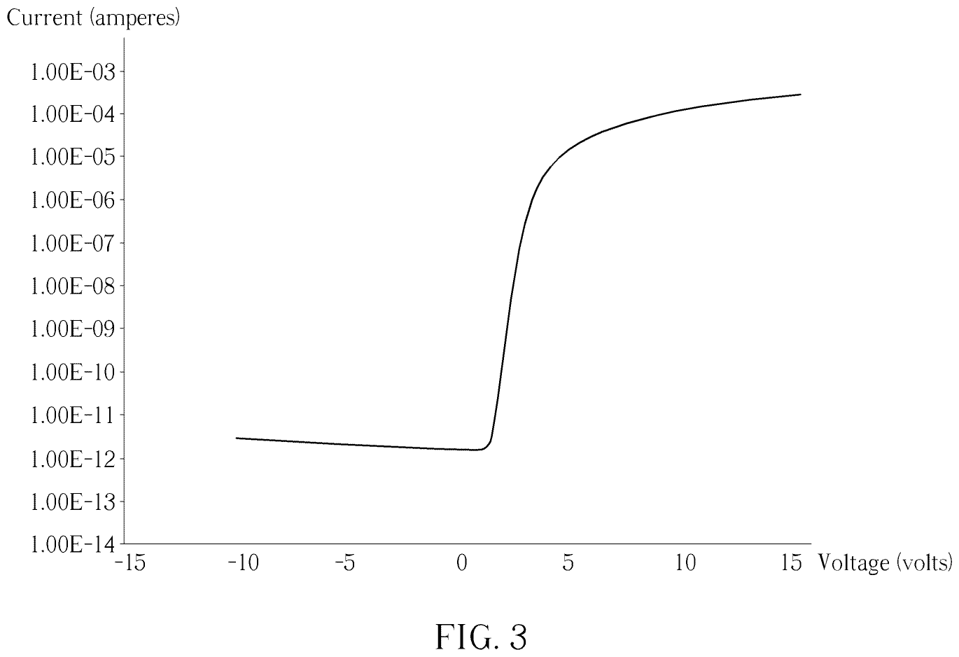

With the aforementioned configuration, the switching element 10A may form a main channel in the second subregion 32. Additionally, because in the top view of the switching element 10A, the first subregions 44 are positioned at the ends of the overlapping region between the semiconductor 20 and the gate 30, and the first subregion 44 is a P-type heavily doped region, the probability of the switching element 10A generating a sub-channel can be reduced. Please refer to FIG. 3. FIG. 3 is a current-voltage (I-V) curve diagram of the switching element 10A in FIG. 1. The horizontal coordinate in FIG. 3 represents the drain-source voltage of the switching element 10A . in volts, V), and the vertical coordinate in FIG. 3 represents the current from the drain region to the source region of the switching element 10A (in amperes, I). In one embodiment, when the switching element 10A does not have a sub-channel, the current-voltage curve of the switching element 10A will not have a hump. A hump refers to an abnormal peak in the current-voltage curve, which adversely affects the performance of the transistor (e.g., reducing the stability of the transistor).

The above embodiment describes the switching element 10A as an N-type transistor as an example. In other embodiments of the present disclosure, the switching element 10A may be a P-type transistor. When the switching element 10A is a P-type transistor, each first subregion 44 may be an N-type heavily doped region (N+), the second subregion 32 may be an N-type lightly doped region (N−), each lightly doped region 34 may be a P-type lightly doped region (P−), and the second region 50 and the third region 60 may be P-type heavily doped regions (P+). The ion concentration doped in each first subregion 44 may be 2 to 1000 times the ion concentration doped in the second subregion 32. The ions doped in the N-type heavily doped regions (N+) and N-type lightly doped regions (N−) may be phosphorus ions or arsenic ions, and the ions doped in the P-type heavily doped regions (P+) and P-type lightly doped regions (P−) may be boron ions, but are not limited thereto.

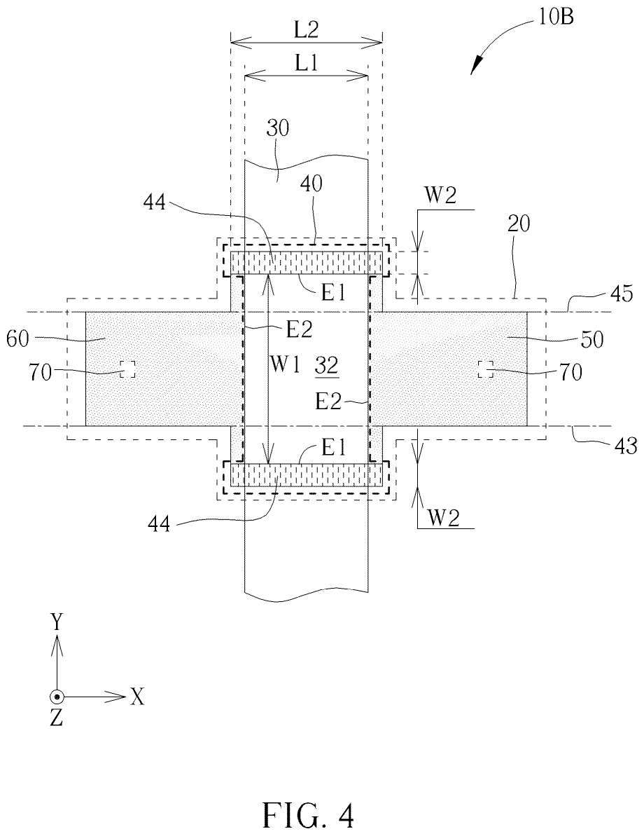

Please refer to FIG. 4. FIG. 4 is a top view of another embodiment of a switching element 10B of the present disclosure. The structure of the switching element 10B is similar to that of the switching element 10A in FIG. 1, and the main difference between the two switching elements 10A and 10B is that the switching element 10B does not include the two lightly doped regions 34 of the switching element 10A. In this embodiment, along the direction X, the two opposite edges E2 of the second subregion 32 are directly connected to the second region 50 and the third region 60, respectively. In other words, the two opposite edges E2 of the second subregion 32 are adjacent to or overlap with the edge of the second region 50 and the edge of the third region 60, respectively. Along the direction Y, each of the two opposite edges E1 of the second subregion 32 is directly connected to one of the first subregions 44. In other words, each of the two opposite edges E1 of the second subregion 32 is partially adjacent to or overlaps with the edge of one of the first subregions 44, and the edge of each first subregion 44 is partially adjacent to or overlaps with the edge of the second region 50 and the edge of the third region 60, respectively. The switching element 10B may be an N-type transistor or a P-type transistor, and the type of ions doped in the regions of the switching element 10B and whether the region is heavily doped or lightly doped may be the same as those of the switching element 10A. Details thereof are not reiterated herein.

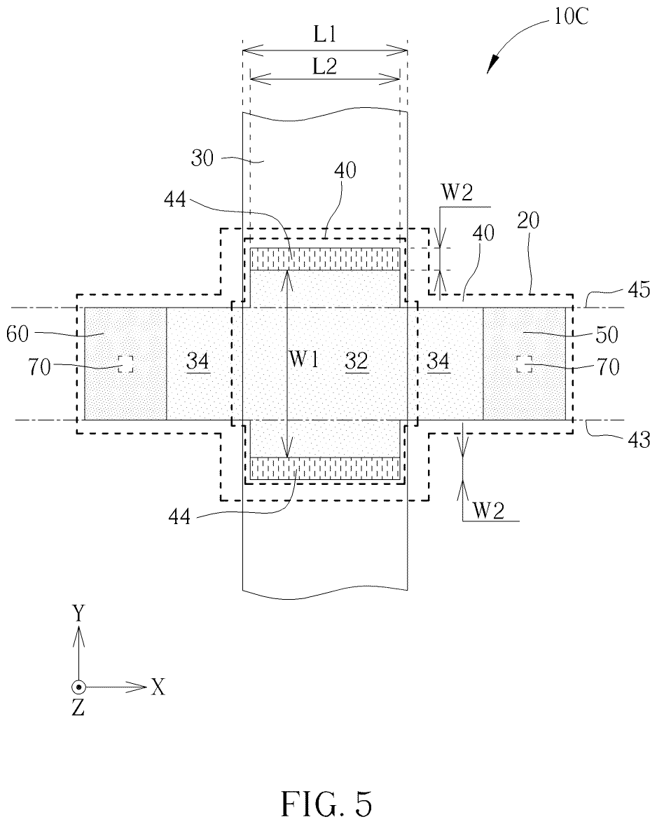

Please refer to FIG. 5. FIG. 5 is a top view of another embodiment of a switching element 10C of the present disclosure. The structure of the switching element 10C is similar to that of the switching element 10A in FIG. 1, and the main difference between the two switching elements 10A and 10C is that the distance L2 in the direction X between the two sides of each first subregion 44 of the switching element 10C is less than the distance L1 in the direction X between the two sides of the gate 30 of the switching element 10C. The switching element 10C may be an N-type transistor or a P-type transistor, and the type of ions doped in the regions of the switching element 10C and whether the region is heavily doped or lightly doped may be the same as those of the switching element 10A. Details thereof are not reiterated herein.

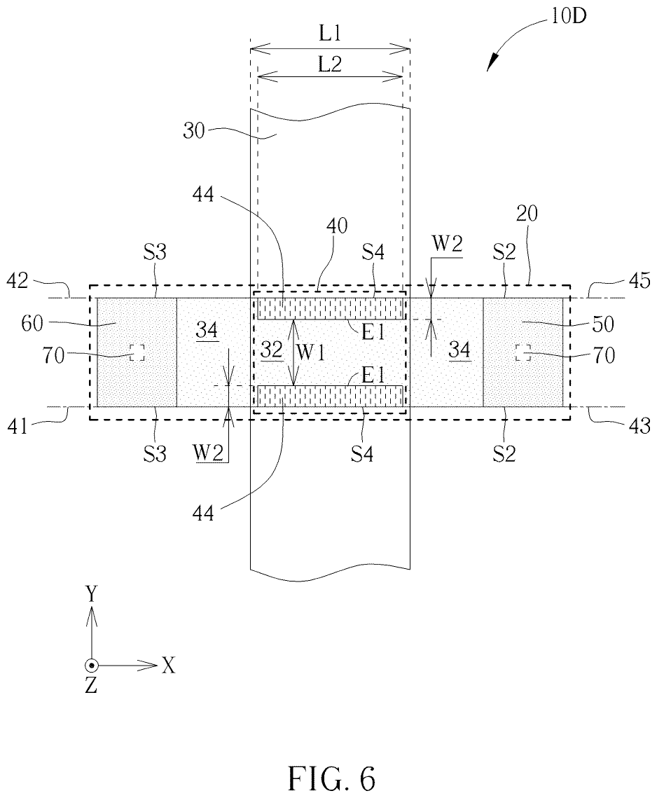

Please refer to FIG. 6. FIG. 6 is a top view of another embodiment of a switching element 10D of the present disclosure. The structure of the switching element 10D is similar to that of the switching element 10C in FIG. 5, and the main difference between the two switching elements 10C and 10D is that a side of each first subregion 44 of the switching element 10D is adjacent to (or overlaps with) a side of the semiconductor 20, and the extension lines 41 and 42 of two opposite sides S4 of the first subregions 44 of the switching element 10D overlap with the connection lines 43 and 45, respectively, and each first subregion 44 of the switching element 10D is disposed within the region formed between the connection lines 43 and 45. In other words, an edge of each first subregion 44 is directly connected to the second subregion 32, an edge of each first subregion 44 is directly connected to the lightly doped region 34 adjacent to the second region 50, and another edge of each first subregion 44 is directly connected to the lightly doped region 34 adjacent to the third region 60. The descriptions of the connection lines 43 and 45 can refer to the descriptions in the previous embodiments. In addition, in this embodiment, along the direction Y, the distance W2 between the side (e.g., a side S4 adjacent to the semiconductor 20) and an edge (e.g., an edge E1 adjacent to the second subregion 32) of each first subregion 44 is less than the distance W1 between the two edges E1 of the second subregion 32. The side and edge of each first subregion 44 and the two edges E1 of the second subregion 32 mentioned here may be parallel to the direction X. In addition, the distance L2 in the direction X between the two sides of each first subregion 44 is less than the distance L1 in the direction X between the two sides of the gate 30. In other embodiments of the present disclosure, the distance L2 in the direction X between the two sides of each first subregion 44 may be equal to the distance L1 in the direction X between the two side edges of the gate 30. The two sides of each first subregion 44 and the two sides of the gate 30 described herein may be, for example, parallel to the direction Y. In other embodiments of the present disclosure, the two sides of each first subregion 44 and the two sides of the gate 30 are not all parallel to the direction Y, but the distance L2 between the two sides of each first subregion 44 and the distance L1 between the two sides of the gate 30 may be measured in a cross section parallel to the direction X. In addition, the switching element 10D may be an N-type transistor or a P-type transistor, and the type of ions doped in the regions of the switching element 10D and whether the region is heavily doped or lightly doped may be the same as those of the switching element 10A. Details thereof are not reiterated herein.

In some embodiments of the present disclosure, the ratio of the distance W2 to the distance W1 may be between 0.005 and 1.

The switching elements of the above embodiments of the present disclosure, by setting at least a first subregion 44 at the edge of the overlapping region between the semiconductor 20 and the gate 30, reduces the generation of a sub-channel in the switching element, thereby reducing the hump distribution of the current-voltage curve of the switching elements and improving the stability of the switching elements.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A switching element comprising:
a gate; and
a semiconductor comprising a first region, a second region, and a third region, the first region being located between the second region and the third region, the first region comprising at least one first subregion and a second subregion other than the at least one first subregion, and the at least one first subregion being adjacent to a side of the semiconductor;
wherein, in a top view of the switching element, at least a portion of the first region overlaps with the gate; and
wherein an ion concentration doped in the at least one first subregion is different from an ion concentration doped in the second subregion.

2. The switching element of claim 1, wherein an extension line of a side of the at least one first subregion overlaps with a connection line of a side of the second region and a side of the third region.

3. The switching element of claim 2, wherein the second region and the third region are arranged along a first direction, and a distance in the first direction between two opposite edges of the at least one first subregion is less than or equal to a distance in the first direction between two opposite sides of the gate.

4. The switching element of claim 2, further comprising a lightly doped region disposed between the first region and the second region.

5. The switching element of claim 1, wherein at least a portion of the at least one first subregion is disposed outside an area formed by two connection lines of opposite sides of the second region and opposite sides of the third region.

6. The switching element of claim 5, wherein the second region and the third region are arranged along a first direction, and a distance in the first direction between two opposite sides of the at least one first subregion is greater than or equal to a distance in the first direction between two opposite sides of the gate.

7. The switching element of claim 5, wherein the second region and the third region are arranged along a first direction, and a distance in the first direction between two opposite sides of the at least one first subregion is less than a distance in the first direction between two opposite sides of the gate.

8. The switching element of claim 7, further comprising a lightly doped region disposed between the first region and the second region.

9. The switching element of claim 1, wherein the at least one first subregion is directly connected to the second subregion.

10. The switching element of claim 1, wherein a ratio of an ion concentration doped in the at least one first subregion to an ion concentration doped in the second subregion is greater than or equal to 2 and less than or equal to 1000.

11. A switching element comprising:
a gate; and
a semiconductor comprising a first region, a second region, and a third region, the first region being located between the second region and the third region, the first region comprising two first subregions and a second subregion other than the two first subregions, and each first subregion being adjacent to a corresponding side of the semiconductor;
wherein, in a top view of the switching element, at least a portion of the each first subregion overlaps with the gate; and
wherein an ion concentration doped in the each first subregion is different from an ion concentration doped in the second subregion.

12. The switching element of claim 11, wherein an extension line of a side of the each first subregion overlaps with a connection line of a side of the second region and a side of the third region.

13. The switching element of claim 12, wherein the second region and the third region are arranged along a first direction, and a distance in the first direction between two opposite edges of the each first subregion is less than or equal to a distance in the first direction between two opposite sides of the gate.

14. The switching element of claim 12, further comprising a lightly doped region disposed between the first region and the second region.

15. The switching element of claim 11, wherein at least a portion of the each first subregion is disposed outside an area formed by two connection lines of opposite sides of the second region and opposite sides of the third region.

16. The switching element of claim 15, wherein the second region and the third region are arranged along a first direction, and a distance in the first direction between two opposite sides of the each first subregion is greater than or equal to a distance in the first direction between two opposite sides of the gate.

17. The switching element of claim 15, wherein the second region and the third region are arranged along a first direction, and a distance in the first direction between two opposite sides of the each first subregion is less than a distance in the first direction between two opposite sides of the gate.

18. The switching element of claim 17, further comprising a lightly doped region disposed between the first region and the second region.

19. The switching element of claim 11, wherein the two first subregions are directly connected to the second subregion.

20. The switching element of claim 11, wherein a ratio of an ion concentration doped in the each first subregion to an ion concentration doped in the second subregion is greater than or equal to 2 and less than or equal to 1000.
